(19) United States
(12) Patent Application Publication
(10) Pub. No.: US 2025/0062245 A1
(43) Pub. Date: Feb. 20, 2025

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: Hsien-Wei Chen, Hsinchu City (TW); Meng-Liang Lin, Hsinchu (TW); Ying-Ju Chen, Yunlin County (TW); Shin-Puu Jeng, Hsinchu (TW)

(73) Assignee: Taiwan Semiconductor Manufacturing Company, Ltd., Hsinchu (TW)

(21) Appl. No.: 18/449,715

(22) Filed: Aug. 15, 2023

(51) Int. Cl. H01L 23/00; H01L 23/31; H01L 23/538; H01L 25/00; H01L 25/065; H01L 25/10

(52) U.S. Cl. CPC H01L 23/562; H01L 23/3157; H01L 23/5383; H01L 25/0655; H01L 25/105; H01L 25/50; H01L 24/16; H01L 24/32; H01L 24/73; H01L 2224/16227; H01L 2224/32225; H01L 2224/73204

(57) ABSTRACT

A semiconductor structure includes a circuit substrate, at least one semiconductor package, at least one semiconductor device, and a ring structure. The at least one semiconductor package is disposed on the circuit substrate, and the semiconductor package includes a plurality of integrated circuit structures. The at least one semiconductor device, disposed on the circuit substrate and aside the semiconductor package. The ring structure is disposed on the circuit board. The ring structure includes at least one opening pattern corresponding to the semiconductor device.

### BACKGROUND

The semiconductor industry has experienced rapid growth due to continuous improvements in the integration density of a variety of electronic components, such as transistors, diodes, resistors, capacitors, etc. For the most part, this improvement in integration density has come from repeated reductions in minimum feature size, which allows more components to be integrated into a given area. As the demand for shrinking electronic devices has grown, a need for smaller and more creative packaging techniques of integrated circuit structures has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 4 are cross-sectional views of a method of forming a semiconductor structure in accordance with some embodiments.

FIG. 5 is a simplified top view of a semiconductor structure in accordance with some embodiments.

FIG. 6 is a cross-sectional view of a semiconductor structure in accordance with some embodiments.

FIG. 7 is a cross-sectional view of a semiconductor structure in accordance with some embodiments.

FIG. 8 is a simplified top view of a semiconductor structure in accordance with some embodiments.

FIG. 9 is a cross-sectional view of a semiconductor structure in accordance with some embodiments.

FIG. 10 is a simplified top view of a semiconductor structure in accordance with some embodiments.

FIG. 11 is a cross-sectional view of a semiconductor structure in accordance with some embodiments.

FIG. 12 is a cross-sectional view of a semiconductor structure in accordance with some embodiments.

FIG. 13 is a simplified top view of a semiconductor structure in accordance with some embodiments.

FIG. 14 to FIG. 16 are cross-sectional views of semiconductor structures in accordance with some embodiments.

FIG. 17 illustrates a process flow of forming a semiconductor structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure relates to a semiconductor device and its forming method. In some embodiments, a semiconductor device includes semiconductor package(s) and semiconductor device(s) around the semiconductor package(s), which are laterally disposed and electrically connected to a circuit substrate. In some embodiments, a ring structure is disposed on the circuit substrate to encircle the semiconductor device(s). The ring structure of the disclosure has an overhang portion across the semiconductor device(s), and the overhang portion has opening pattern(s) corresponding to the underlying semiconductor device(s). In some embodiments, by including such ring structure with opening pattern(s), the warpage of the 3DIC semiconductor structure may be effectively controlled without contacting the underlying semiconductor device(s), thus enhancing yield and reliability of the semiconductor device.

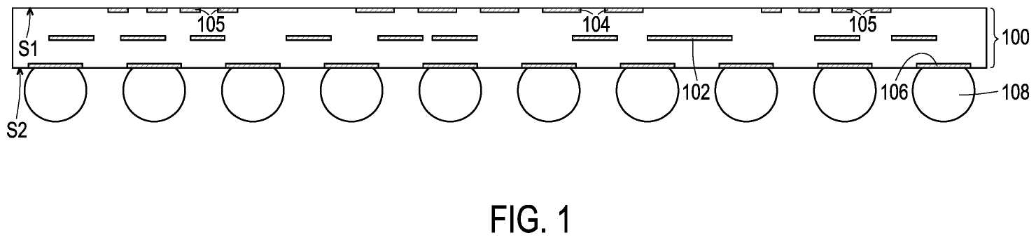

FIG. 1 to FIG. 4 are cross-sectional views of a method of forming a semiconductor structure in accordance with some embodiments. It is understood that the disclosure is not limited by the method described below. Additional operations can be provided before, during, and/or after the method and some of the operations described below can be replaced or eliminated, for additional embodiments of the methods.

Referring to FIG. 1, a circuit substrate 100 is provided. In some embodiments, the circuit substrate 100 includes a core layer and two build-up layers on opposite sides of the core layer. In some embodiments, the core layer includes prepreg, polyimide, photo image dielectric (PID), Ajinomoto buildup film (ABF), the like, or a combination thereof. However, the disclosure is not limited thereto, and other dielectric materials may also be used. In some embodiments, each of build-up layer includes dielectric layers, such as polyimide, polybenzoxazole (PBO), benzocyclobutene (BCB), prepreg, Ajinomoto buildup film (ABF), silicon nitride, silicon oxide, the like, or a combination thereof. The material of the core layer may be different from the material of the build-up layers. In some embodiments, the circuit substrate 100 includes wiring patterns 102 that penetrate through the core layer and the build-up layers for providing electrical routing between different components. The wiring patterns 102 include lines, vias, pads and/or connectors. The wiring patterns 102 include Cu, Al, Ti, Ta, W, Ru, Co, Ni, the like, or a combination thereof. In some embodiments, the circuit substrate 100 has first pads 104, 105 at a first side S1 and second pads 106 at a second side S2 opposite to the first side S1. The first pads 104, 105 and the second pads 106 are configured to connect to bumps and/or components. In some embodiments, first and second mask layers are formed on the first side S1 and the second side S2, respectively. The first and second mask layers may include materials having a chemical composition of silica, barium sulfate and epoxy resin, and/or the like. The first and second mask layers may cover portions of the first and second pads 104, 105 and 106 while expose portions of the first and second pads 104, 105 and 106 for bumps and/or components. In some embodiments, the first pads 104, 105 of the circuit substrate 100 at the first side S1 are electrically connected at least one semiconductor package and/or semiconductor device, and the second pads 106 of the circuit substrate 100 at the second side S2 are electrically connected to bumps 108. The bumps 108 are referred to as “ball grid array (BGA) balls” in some examples. The circuit substrate 100 is referred to as a “board substrate” or “printed circuit board (PCB)” in some examples. In other embodiments, the core layer of circuit substrate 100 may be omitted as needed, and such circuit substrate 100 is referred to as a “coreless circuit substrate”.

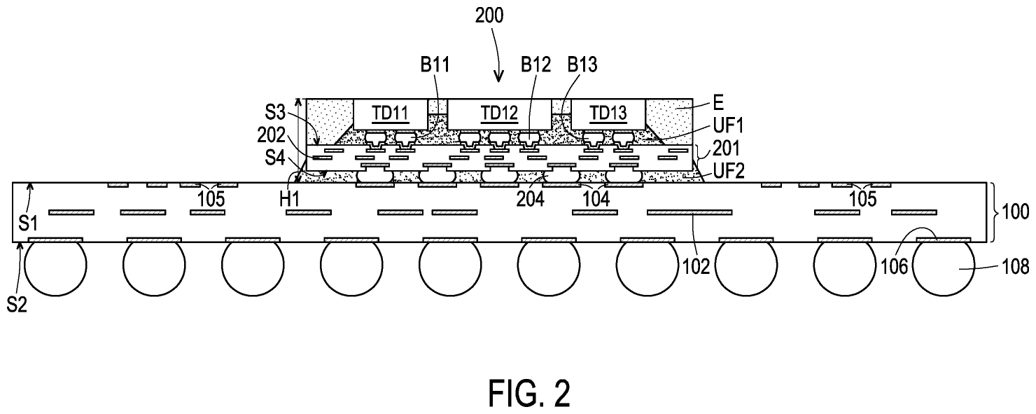

Referring to FIG. 2, at least one semiconductor package 200 is provided and bonded to the first side S1 of the circuit substrate 100. In some embodiments, the semiconductor package 200 includes an interposer 201 and multiple integrated circuit structures TD11, TD12 and TD3 disposed on the interposer 201. In some embodiments, the semiconductor package 200 is referred to as a “chip-on-wafer (CoW) module” in some embodiments.

The interposer 201 is configured to provide electrical connection between components. In some embodiments, the interposer 201 is a silicon-free substrate including wring layers 202 embedded by polymer layers. The wring layers 202 include metal lines and/or metal vias. In some embodiments, each wring layer 202 includes Cu, Al, Ti, Ta, W, Ru, Co, Ni, the like, or a combination thereof. In some embodiments, a seed layer and/or a barrier layer may be disposed between each wiring layer 202 and the adjacent polymer layer. The seed layer may include Ti/Cu. The barrier layer may include Ta, TaN, Ti, TiN, CoW or a combination thereof. In some embodiments, each polymer layer includes an organic material, such as polybenzoxazole (PBO), polyimide (PI), benzocyclobutene (BCB), the like, or a combination thereof. The interposer 201 may be referred to an “organic interposer” in some examples. The polymer layers of the interposer 201 may be replaced by dielectric layers or insulating layers as needed. In some embodiments, the interposer 201 is a silicon-containing substrate, and further includes through silicon vias penetrating through the silicon substrate and electrically connected to the wring layers 202.

In some embodiments, the interposer substrate 201 is a passive interposer, which is used to convey a lack of a functional device or integrated circuit device. Such passive interposer is referred to as a “device-free interposer” in some examples.

In other embodiments, the interposer substrate 201 is an active interposer that contains at least one functional device or integrated circuit device embedded in the polymer layers and electrically connected to the wiring layers 202. Such active interposer is referred to as a “device-containing interposer” in some examples.

In some embodiments, the interposer 201 has a first side S3 and a second side S4 opposite to the first side S3. In some embodiments, the interposer 201 is bonded to the first pads 104 of the circuit substrate 100 through bumps 204 at the second side S4 thereof. The bumps 204 are referred to as “controlled collapse chip connection (C4) bumps” in some examples.

The integrated circuit structures TD11, TD12 and TD13 are arranged side by side, disposed over and bonded to the first side S3 of the interposer 201. In some embodiments, the integrated circuit structures TD11 and TD13 are periphery integrated circuit structures around the central integrated circuit structures TD12. In some embodiments, the integrated circuit structures TD11, TD12 and TD13 are electrically connected to the interposer 201 through bumps B11, B12 and B13, respectively. The bumps B11, B12 and B13 are referred to as “micro bumps” in some examples.

Each of the integrated circuit structures TD11, TD12 and TD13 may be a single die or a die stack including multiple dies. The adjacent dies in the die stack may be vertically stacked through a solder joint or a hybrid bonding including a metal-to-metal bonding and a dielectric-to-dielectric bonding. In some embodiments, each of the integrated circuit structures TD11, TD12 and TD13 includes an integrated active device, such as a logic device, a memory device, a MOSFET device, a CMOS device, a BJT device, a system on chip (SoC), the like, or a combination thereof. In some embodiments, at least one of the integrated circuit structures TD11, TD12 and TD13 may be a dummy chip. Herein, a dummy die indicates a non-operating die, a die configured for non-use, a die without devices therein or a die configured to electrically couple together two other components, strengthen the package structure, and/or improve the heat dissipation.

In some embodiments, the integrated circuit structures TD11, TD12 and TD13 may have the same or different sizes and/or functions upon the design requirements. The semiconductor package 200 is referred to as a “homogeneous package” when the integrated circuit structures TD11, TD12 and TD13 have the same function. The semiconductor package 200 is referred to as a “heterogeneous package” when the integrated circuit structures TD11, TD12 and TD13 have different functions.

In some embodiments, the semiconductor package 200 further includes an underfill layer UF1 between the integrated circuit structures TD11, TD12, TD13 and the interposer 201 and around the bumps B11, bumps B12 and B13, and an underfill layer UF2 between the interposer 201 and the circuit substrate 100 around the bumps 204. In some embodiments, the semiconductor package 200 further includes an encapsulation layer E over the interposer 201 and around the integrated circuit structures TD11, TD12 and TD13. In some embodiments, the top surface of the encapsulation layer E is flushed with the top surfaces of the integrated circuit structures TD11, TD12 and TD13.

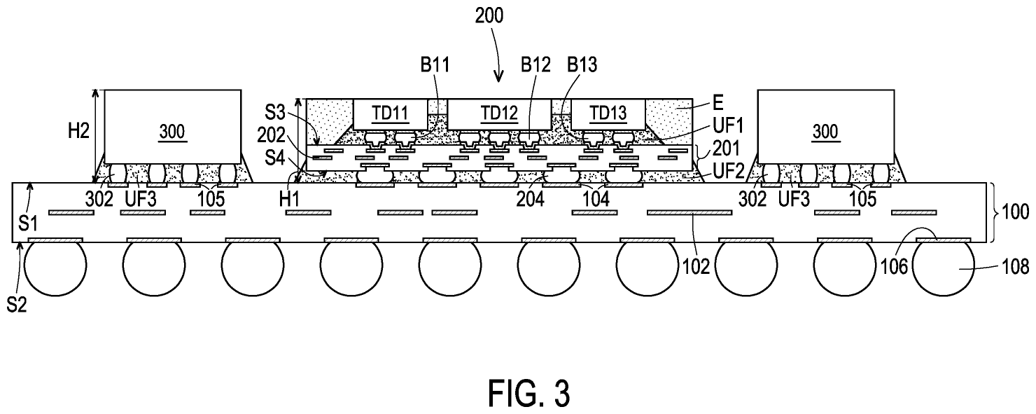

Referring to FIG. 3, multiple semiconductor devices 300 are formed aside the semiconductor package 200. In some embodiments, the semiconductor device 300 includes an integrated passive device, such as a resistor, a capacitor, an inductor, a resonator, a regulator, a filter, the like, or a combination thereof. In some embodiments, the semiconductor device 300 includes an integrated active device, such as a logic device, a memory device, a MOSFET device, a CMOS device, a BJT device, a system on chip (SoC), the like, or a combination thereof. In some embodiments, the semiconductor device 300 is referred to as an “integrated circuit chiplet” or “surface mount device (SMD)” in some embodiments. In some embodiments, the semiconductor device 300 is bonded to the first pads 105 of the circuit substrate 100 through bumps 302. The bumps 302 are referred to as “controlled collapse chip connection (C4) bumps” in some examples. An underfill layer UF3 may be formed between the semiconductor device 300 and the circuit substrate 100 around the bumps 302.

The height H2 of the semiconductor device 300 is higher than the height H1 of the semiconductor package 200, counting from the first surface S1 of the circuit substrate 100. From another point of view, the top surface of the semiconductor device 300 is higher than the top surfaces of the integrated circuit structures TD11, TD12 and TD13 by a non-zero distance.

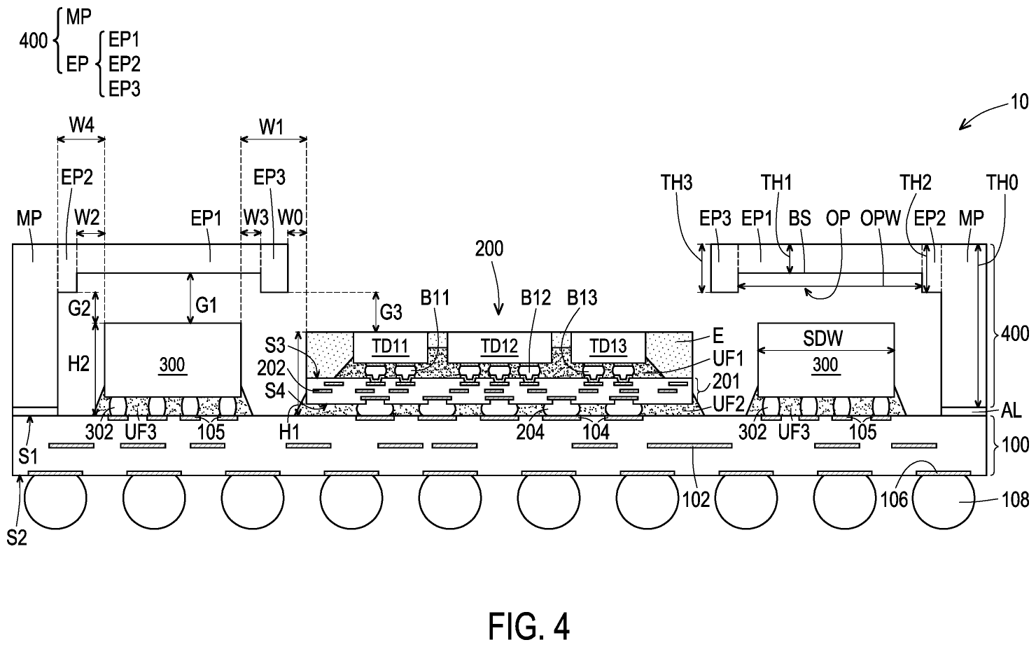

Referring to FIG. 4, a ring structure 400 is bonded to the circuit substrate 100 through an adhesive layer AL. In some embodiments, the ring structure 400 has an annular shape (e.g., square-ring shape) encircling the semiconductor device 300. The ring structure 400 may be placed on the circuit substrate 100 in correspondence of the adhesive layer AL, and bonded to the circuit substrate 100 by curing (or pre-curing) the adhesive layer AL, for example. In some embodiments, the ring structure 400 includes any suitable material, such as metal, metallic alloy, or the like. For example, the ring structure 400 may include stainless steel, copper tungsten, aluminum, the like, or a combination thereof.

In some embodiments, the ring structure 400 includes a main portion MP (or called “base portion” in some examples) contacting the adhesive layer AL and an extending portion EP (or called “overhang portion” in some examples) protruding from the main portion MP towards the semiconductor device 300. Specifically, the extending portion EP of the ring structure 400 may have an inverted-U shape, with at least one opening pattern OP corresponding to the underlying semiconductor device 300 on the circuit substrate 100. In some embodiments, each opening pattern OP has substantially vertical sidewalls. However, the disclosure is not limited thereto. In other embodiments, each opening pattern OP may be a narrow-top and wide-bottom opening having inclined sidewalls. For example, each opening pattern OP may have a trapezoidal shape in a cross-sectional view. The main portion MP and the extending portion EP may be integrally formed as a single piece. In some embodiments, the opening patterns OP of the extending portion EP of the ring structure 400 are patterned by a laser drilling process. In other embodiments, the opening patterns OP of the extending portion EP of the ring structure 400 are patterned by an etching process. Since the height H2 of the semiconductor device 300 is higher than the height H1 of the semiconductor package 200, the conventional ring structure may contact the underlying components when package warpage occurs. However, in the disclosure, by including a ring structure with opening patterns, the warpage of the 3DIC semiconductor structure may be effectively controlled without contacting the underlying semiconductor devices, thus enhancing yield and reliability of the semiconductor device. Upon the formation of the ring structure, a semiconductor structure 10 of the disclosure is thus completed.

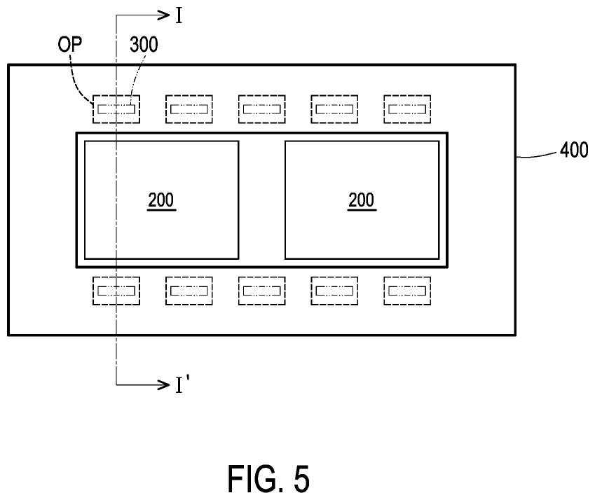

FIG. 5 is a simplified top view of a semiconductor structure in accordance with some embodiments, in which few elements such as semiconductor packages and integrated circuit structures, and ring structure are shown for simplicity and clarity of illustration. In some embodiments, FIG. 4 is the cross-sectional view taken along the line I-I′ of FIG. 5.

As shown in FIG. 5, from a top view, multiple semiconductor packages 200 and multiple semiconductor devices 300 are disposed on a circuit board, and the semiconductor devices 300 are disposed around the semiconductor packages 200. In some embodiments, the semiconductor devices 300 are disposed at opposite sides of the semiconductor packages 200. However, the disclosure is not limited thereto. In other embodiments, the semiconductor devices 300 are disposed at four sides of the semiconductor packages 200. The ring structure 400 has multiple openings OP for providing spaces for the underlying semiconductor devices 300, so as to prevent undesired contact and damage between the semiconductor devices 300 and the ring structure 400.

More specifically, as shown in FIG. 4, each opening pattern OP is defined by three parts EP1, EP2 and EP3 of the extending portion EP of the ring structure 400. The part EP1 is disposed between and in contact with the parts EP2 and EP3, and the part EP2 is connected to the main portion MP. In some embodiments, the thickness TH1 of the part EP1 is thinner than the thickness TH2 of the part EP2 or the thickness TH3 of the part EP3. In some embodiments, the thickness TH2 of the part EP2 is substantially the same as the thickness TH3 of the part EP3, as shown in FIG. 4. Specifically, the extension part EP of the ring structure 400 in FIG. 4 have two different thicknesses. However, the disclosure is not limited thereto. In other embodiments, the thickness TH2 of the part EP2 may be different from the thickness TH3 of the part EP3.

In the extending portion EP of the ring structure 400, the thinner part EP1 is configured to provide enough space for the underlying semiconductor device 300, while thicker parts EP2 and EP1 are configured to strength the package structure and prevent package warpage. In some embodiments, the thickness of the main portion MP of the ring is between about 0.5 mm and 10 mm, the ratio of the thickness TH2 (or TH3) to the thickness TH1 is between about 0.5 and 1.0, and the ratio of the thickness TH1 to the thickness TH2 (or TH3) is between about 0.7 and 1.0. Other ratios may be possible, as long as the ring structure 400 is separated from the underlying semiconductor device 300 or the adjacent semiconductor package by a non-zero distance.

For example, the distance W0 from the part EP3 of the ring structure 400 to the semiconductor package 200 is between about 1 mm and 5 mm. That is, the ring structure 400 is separated from the semiconductor package 200 by a distance W0 (e.g., 1-5 mm). For example, the distance W1 from the semiconductor device 300 to the semiconductor package is between 3 mm and 10 mm. For example, the distance W2 from the part EP2 of the ring structure 400 to the semiconductor device 300 is greater than about 0.1 mm, the distance W3 from the part EP3 of the ring structure 400 to the semiconductor device 300 is greater than about 0.1 mm. For example, the distance W4 from the main portion MP of the ring structure 400 to the semiconductor device 300 is greater than about 1 mm. Other distances may be possible, as long as the ring structure 400 is laterally or vertically separated from the underlying semiconductor device 300 or the adjacent semiconductor package 200 by a non-zero distance.

For example, the gap distance G1 from the part EP1 of the ring structure 400 to the semiconductor device 300 is greater than about 200 μm. For example, the gap distance G2 from the part EP2 of the ring structure 400 to the semiconductor device 300 is between 0 μm and 200 μm. For example, the gap distance G3 from the part EP3 of the ring structure 400 to the semiconductor package 300 is greater than 200 μm. Other gap distances may be possible, as long as the ring structure 400 is separated from the underlying semiconductor device 300 or the adjacent semiconductor package by a non-zero distance.

Besides, as shown in FIG. 4, the width OPW of the opening pattern OP of the ring structure 400 is greater than the width SDW of the underlying semiconductor device 300 by a non-zero distance, such as greater than about 0.2 mm or more. From a top view, the ring structure 400 of the disclosure is separated from or non-overlapped with the semiconductor package 200, as shown in FIG. 5.

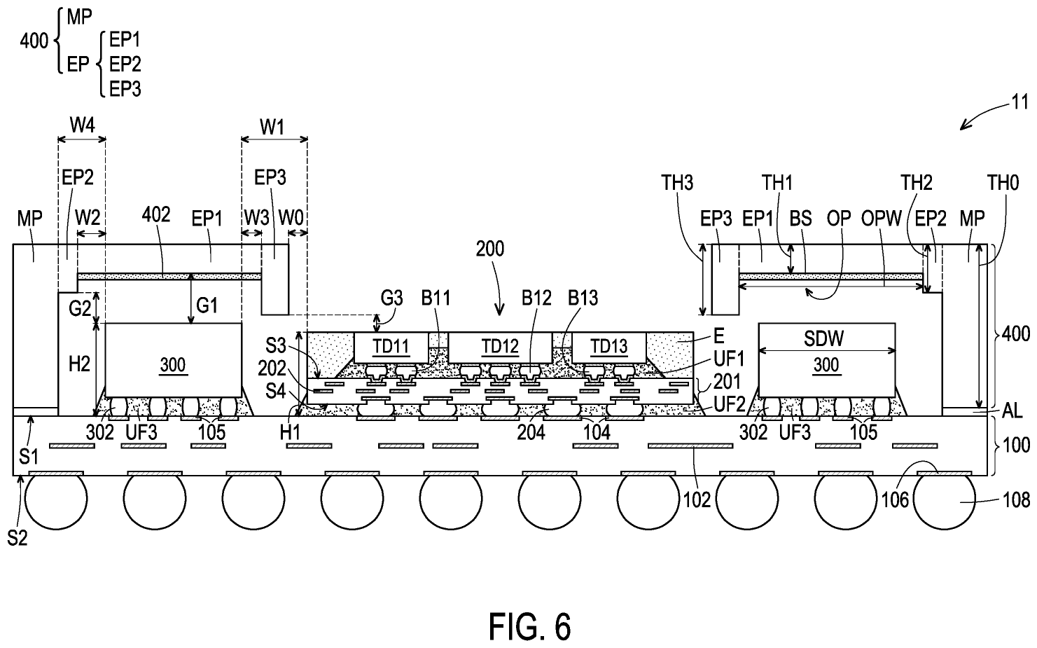

FIG. 6 is a cross-sectional view of a semiconductor structure in accordance with some embodiments. The semiconductor structure 11 of FIG. 6 is similar to the semiconductor structure 10 of FIG. 4, so the difference is described below, and the similarity is not iterated herein.

One difference between the semiconductor structure 11 and the semiconductor structure 10 lies in that, in the semiconductor structure 11, a buffer layer 402 is further attached to the ring structure 400 so as to provide more protection for the underlying semiconductor device 300. Specifically, after forming opening patterns OP in the extension portion EP of the ring structure 400 and before mounting the ring structure 400 on the circuit substrate 100, a buffer layer 402 is formed on the bottom surface BS of the extension portion EP. In some embodiments, the buffer layer 402 includes a dielectric material, a soft material or an elastic material, such as rubber, polymer (e.g., epoxy) or tape (e.g., die attach film), or the like. The hardness of the buffer layer 402 is less than the hardness of the ring structure. In some embodiments, the thickness of the buffer layer 402 ranges from about 10 μm to 60 μm. In some embodiments, the buffer layer 402 is formed on a portion of the bottom surface BS of the extension portion EP (i.e., the bottom surface of the part EP1), as shown in FIG. 6. However, the disclosure is not limited thereto. In other embodiments, the buffer layer 402 may be formed on the entire bottom surface BS of the extension portion EP. Another difference between the semiconductor structure 11 and the semiconductor structure 10 lies in that, in the semiconductor structure 11, the thickness TH3 of the part EP3 is different from (e.g., greater than) the thickness TH2 of the part EP2. Specifically, the extension part EP of the ring structure 400 in FIG. 6 have three different thicknesses.

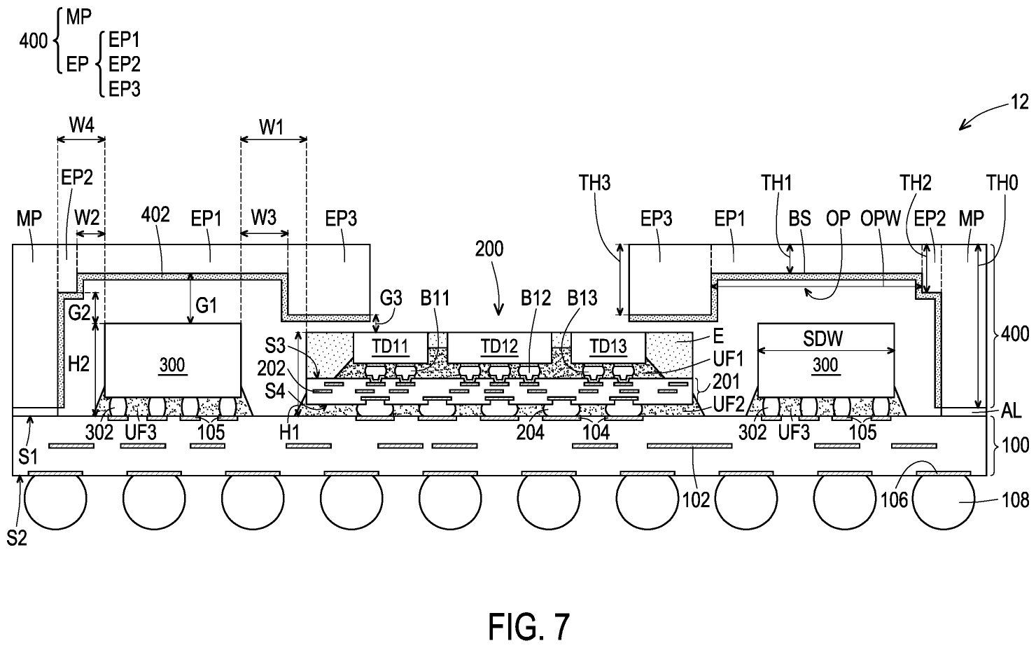

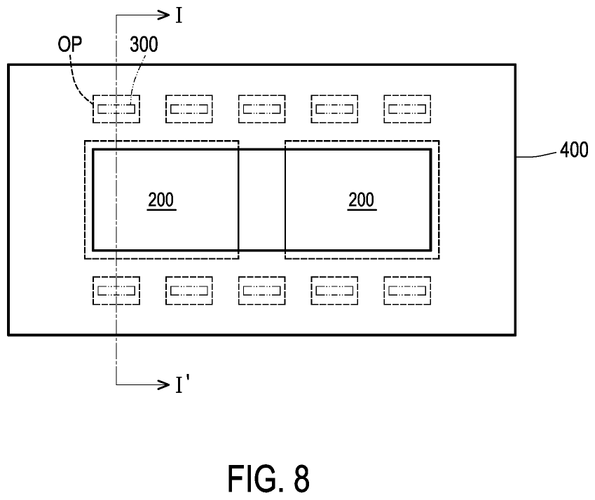

FIG. 7 is a cross-sectional view of a semiconductor structure in accordance with some embodiments. FIG. 8 is a simplified top view of a semiconductor structure in accordance with some embodiments. In some embodiments, FIG. 7 is the cross-sectional view taken along the line I-I′ of FIG. 8.

The semiconductor structure 12 of FIG. 7 is similar to the semiconductor structure 10 of FIG. 4, so the difference is described below, and the similarity is not iterated herein. One difference between the semiconductor structure 12 and the semiconductor structure 10 lies in that, in the semiconductor structure 12, a buffer layer 402 is further attached to the ring structure 400 so as to provide more protection for the underlying semiconductor device 300. In some embodiments, the buffer layer 402 is formed not only on the entire bottom surface BS of the extension portion EP but also on the sidewall of the main portion MP, as shown in FIG. 7. In some embodiments, the sidewall of the buffer layer 402 may be protruded from the sidewall of the adhesion layer AL, as shown in FIG. 7. In other embodiments, the sidewall of the buffer layer 402 may be flushed with the sidewall of the adhesion layer AL. Another difference between the semiconductor structure 12 and the semiconductor structure 10 lies in that, in the semiconductor structure 12, the extension part EP of the ring structure 400 laterally extends across not only the semiconductor device 300 but also a portion of the semiconductor package 200. Specifically, from a top view, the ring structure 400 is partially overlapped with the semiconductor package 200, as shown in FIG. 8.

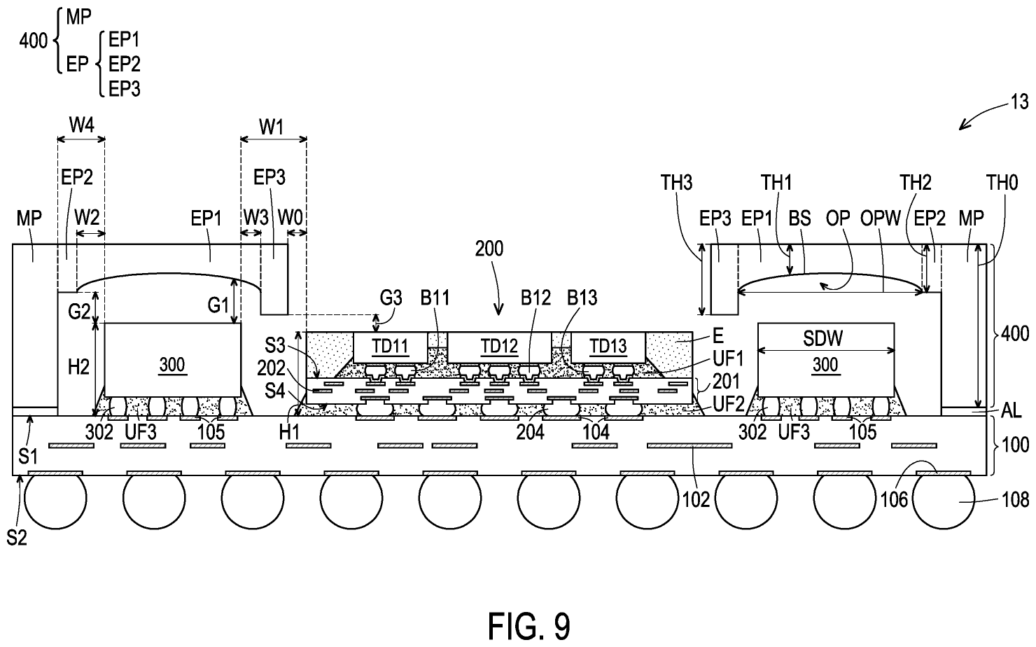

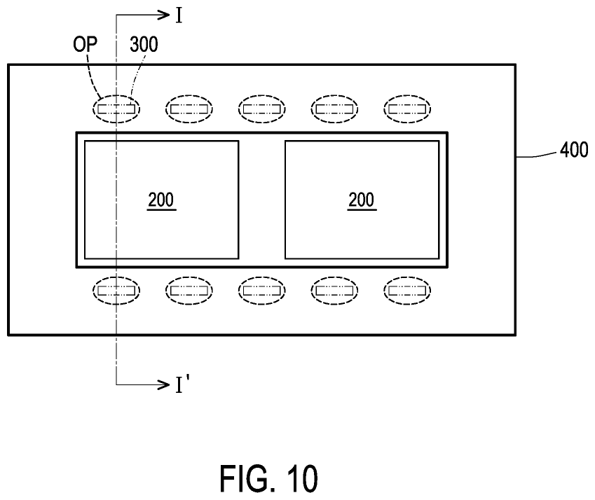

FIG. 9 is a cross-sectional view of a semiconductor structure in accordance with some embodiments. FIG. 10 is a simplified top view of a semiconductor structure in accordance with some embodiments. In some embodiments, FIG. 9 is the cross-sectional view taken along the line I-I′ of FIG. 10.

The semiconductor structure 13 of FIG. 9 is similar to the semiconductor structure 10 of FIG. 4, so the difference is described below, and the similarity is not iterated herein. One difference between the semiconductor structure 13 and the semiconductor structure 10 lies in that, in the semiconductor structure 13, the thickness of the part EP1 of the extension portion EP is continuously varied from one end adjacent to the part EP2 to another end adjacent to the part EP3. Specifically, in the semiconductor structure 13, each opening pattern OP of the ring structure 400 has a dome shape in a cross-sectional view (as shown in FIG. 9), and has a circular shape in a top view (as shown in FIG. 10). In some embodiments, from a top view, the ring structure 400 of the semiconductor structure 13 is separated from the semiconductor package 200, as shown in FIG. 10. However, the disclosure is not limited thereto. In some embodiments, from a top view, the ring structure 400 of the semiconductor structure 13 may be partially overlapped with the semiconductor package 200.

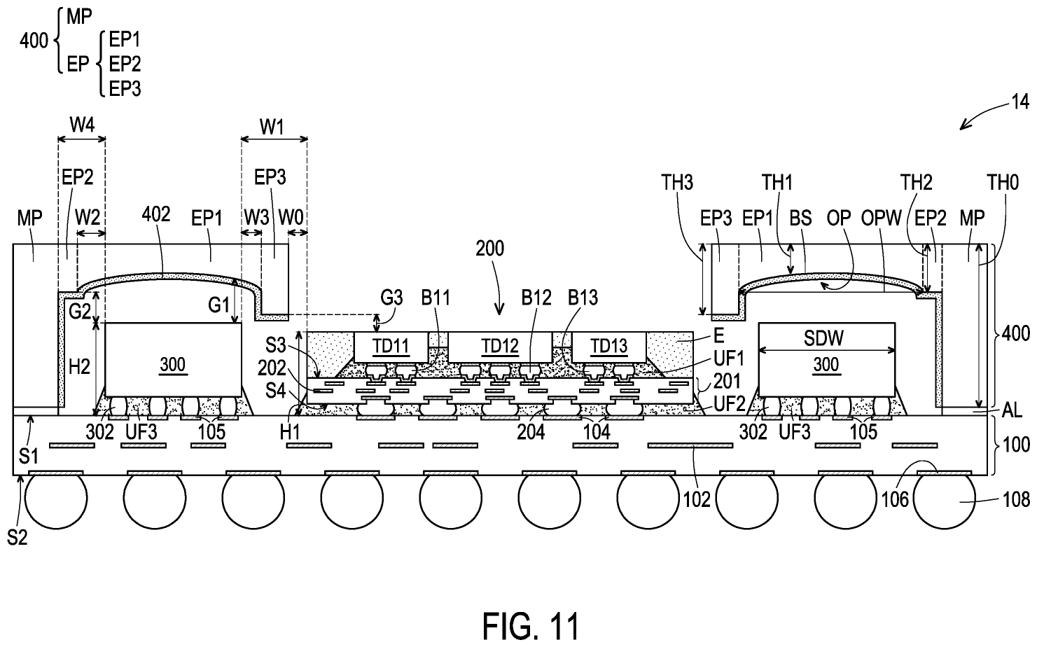

FIG. 11 is a cross-sectional view of a semiconductor structure in accordance with some embodiments. The semiconductor structure 14 of FIG. 11 is similar to the semiconductor structure 13 of FIG. 9, so the difference is described below, and the similarity is not iterated herein. The difference between the semiconductor structure 14 and the semiconductor structure 13 lies in that, in the semiconductor structure 14, a buffer layer 402 is further attached to the ring structure 400 so as to provide more protection for the underlying semiconductor device 300. Specifically, after forming opening patterns OP in the extension portion EP of the ring structure 400 and before mounting the ring structure 400 on the circuit substrate, a buffer layer 402 is formed on the bottom surface BS of the extension portion EP. In some embodiments, the buffer layer 402 includes a dielectric material, a soft material or an elastic material, such as rubber, polymer (e.g., epoxy) or tape (e.g., die attach film), or the like. The hardness of the buffer layer 402 is less than the hardness of the ring structure. In some embodiments, the thickness of the buffer layer 402 ranges from about 10 μm to 60 μm. In some embodiments, the buffer layer 402 may be formed not only on the entire bottom surface BS of the extension portion EP but also on the sidewall of the main portion MP, as shown in FIG. 11.

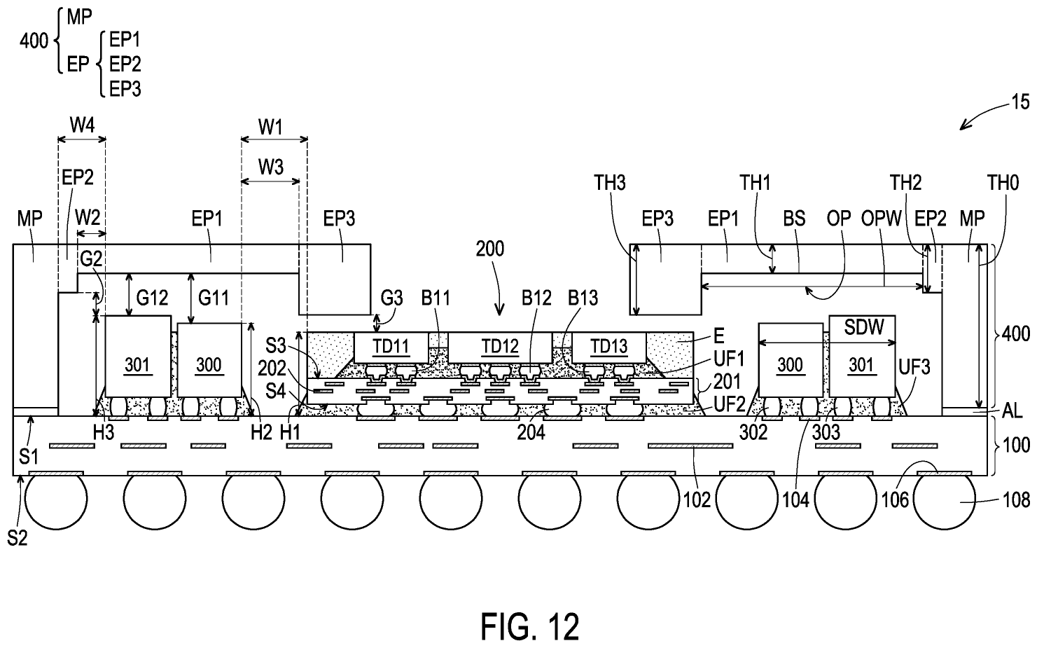

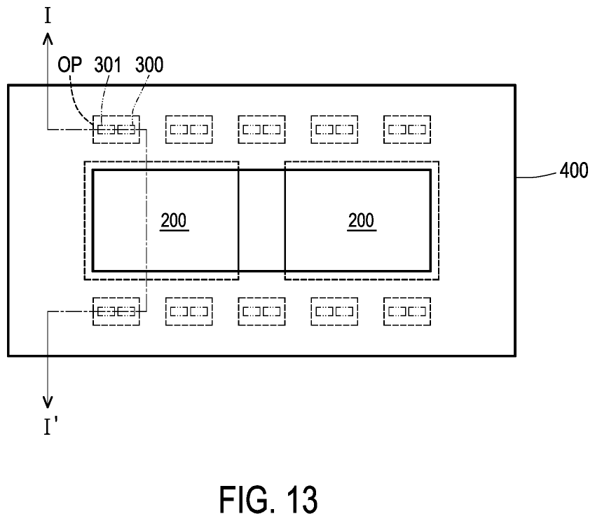

FIG. 12 is a cross-sectional view of a semiconductor structure in accordance with some embodiments. FIG. 13 is a simplified top view of a semiconductor structure in accordance with some embodiments. In some embodiments, FIG. 13 is the cross-sectional view taken along the line I-I′ of FIG. 12.

The semiconductor structure 15 of FIG. 12 is similar to the semiconductor structure 10 of FIG. 4, so the difference is described below, and the similarity is not iterated herein. One difference between the semiconductor structure 15 and the semiconductor structure 10 lies in that, in the semiconductor structure 15, each opening pattern OP corresponds to multiple semiconductor devices (e.g., semiconductor devices 300 and 301). The number of the semiconductor devices is not limited by the present disclosure. For example, each opening pattern OP may correspond to two or more semiconductor devices.

In some embodiments, each of the semiconductor devices 300 and 301 includes an integrated passive device, such as a resistor, a capacitor, an inductor, a resonator, a regulator, a filter, the like, or a combination thereof. In some embodiments, each of the semiconductor devices 300 and 301 includes an integrated active device, such as a logic device, a memory device, a MOSFET device, a CMOS device, a BJT device, a system on chip (SoC), the like, or a combination thereof. The semiconductor devices 300 and 301 may have the same or different functions, sizes, heights and/or widths. In some embodiments, the semiconductor device 300 is bonded to the first pads 105 of the circuit substrate 100 through bumps 302, and the semiconductor device 301 is bonded to the first pads 105 of the circuit substrate 100 through bumps 303. An underfill layer UF3 may be formed between the circuit substrate 100 and each of the semiconductor devices 300 and 301 and around the bumps 302 and 303.

In some embodiments, each of the height H2 of the semiconductor device 300 and the height H3 of the semiconductor device 301 is higher than the height H1 of the semiconductor package 200, counting from the first surface S1 of the circuit substrate 100. From another point of view, the top surfaces of the semiconductor devices 300 and 301 are higher than the top surfaces of the integrated circuit structures TD11, TD12 and TD13 by a non-zero distance. However, the disclosure is not limited thereto. In other embodiments, the height of at least one of multiple semiconductor devices may be higher than the height H1 of the semiconductor package 200, while the height of at least one of multiple semiconductor devices may be lower than the height H1 of the semiconductor package 200.

Another difference between the semiconductor structure 15 and the semiconductor structure 10 lies in that, in the semiconductor structure 15, the extension part EP of the ring structure 400 laterally extends across not only the semiconductor devices 300 and 301 but also a portion of the semiconductor package 200. Specifically, from a top view, the ring structure 400 is partially overlapped with the semiconductor package 200, as shown in FIG. 13.

The width OPW of the opening pattern OP of the ring structure is greater than the total width SDW of the underlying semiconductor devices 300 and 301 by a non-zero distance, such as greater than about 0.2 mm or more. Besides, the gap distance G11 between the part EP1 of the ring structure 400 to the semiconductor device 300 is greater than about 200 μm, and the gap distance G12 between the part EP1 of the ring structure 400 to the semiconductor device 301 is greater than about 200 μm.

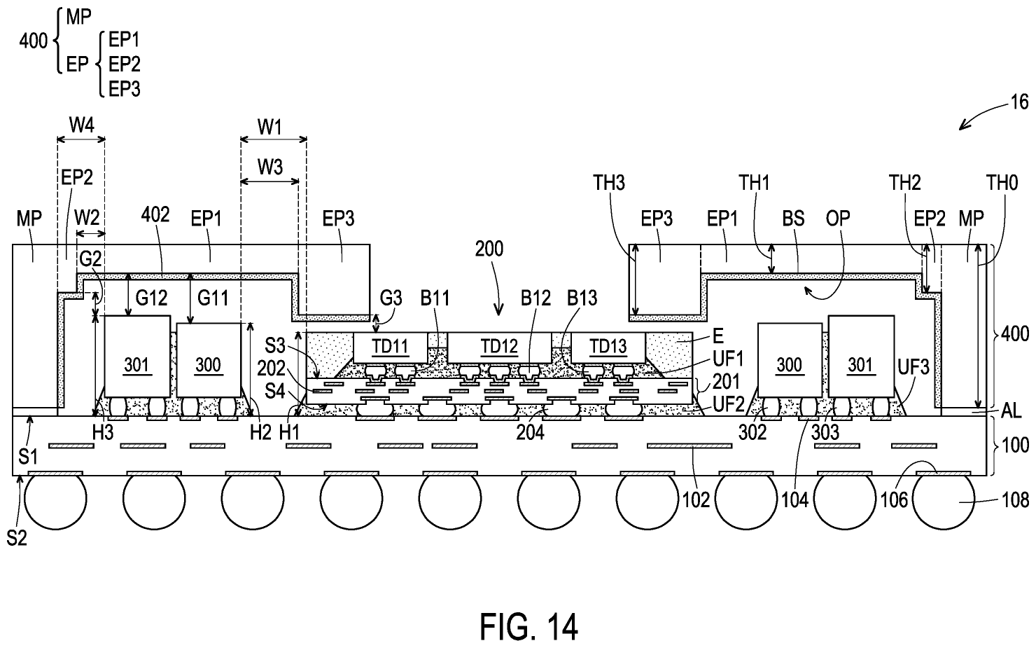

FIG. 14 is a cross-sectional view of a semiconductor structure in accordance with some embodiments. The difference between the semiconductor structure 16 and the semiconductor structure 15 lies in that, in the semiconductor structure 16, a buffer layer 402 is further attached to the ring structure 400 so as to provide more protection for the underlying semiconductor devices 300 and 301. In some embodiments, the buffer layer 402 is formed not only on the entire bottom surface BS of the extension portion EP but also on the sidewall of the main portion MP, as shown in FIG. 14.

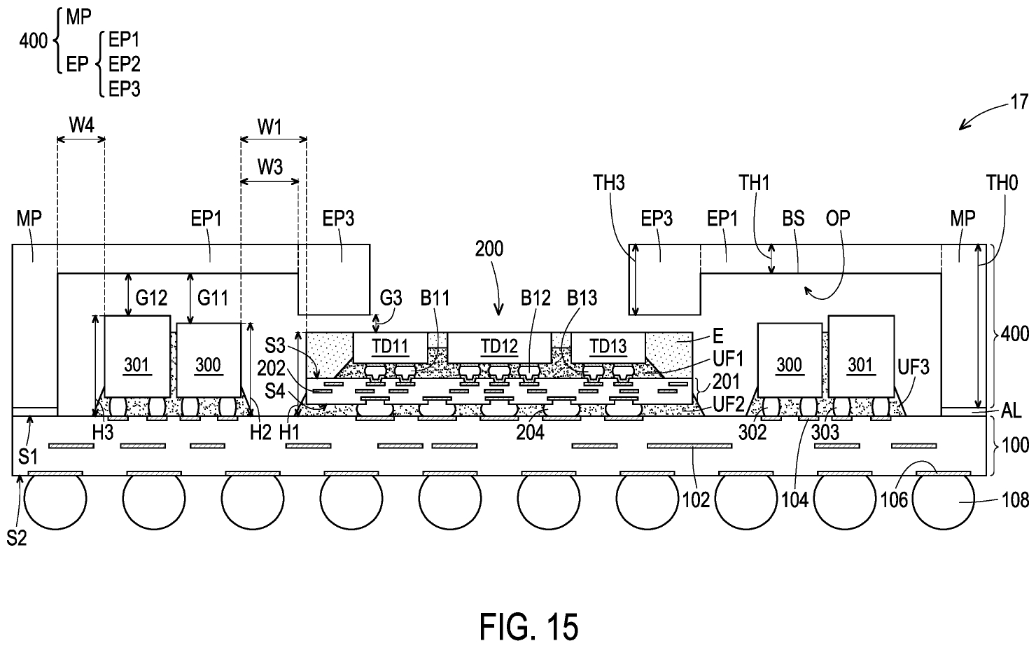

FIG. 15 is a cross-sectional view of a semiconductor structure in accordance with some embodiments. The difference between the semiconductor structure 17 and the semiconductor structure 14 lies in that, in the semiconductor structure 17, a part EP2 is omitted from the extension part EP of the ring structure. As shown in FIG. 15, each opening pattern OP is defined by the main portion MP, and parts EP1, EP3 of the extending portion EP of the ring structure 400. The part EP1 is disposed between and in contact with the main portion MP and the part EP3. Specifically, the extension part EP of the ring structure 400 in FIG. 15 have two different thicknesses.

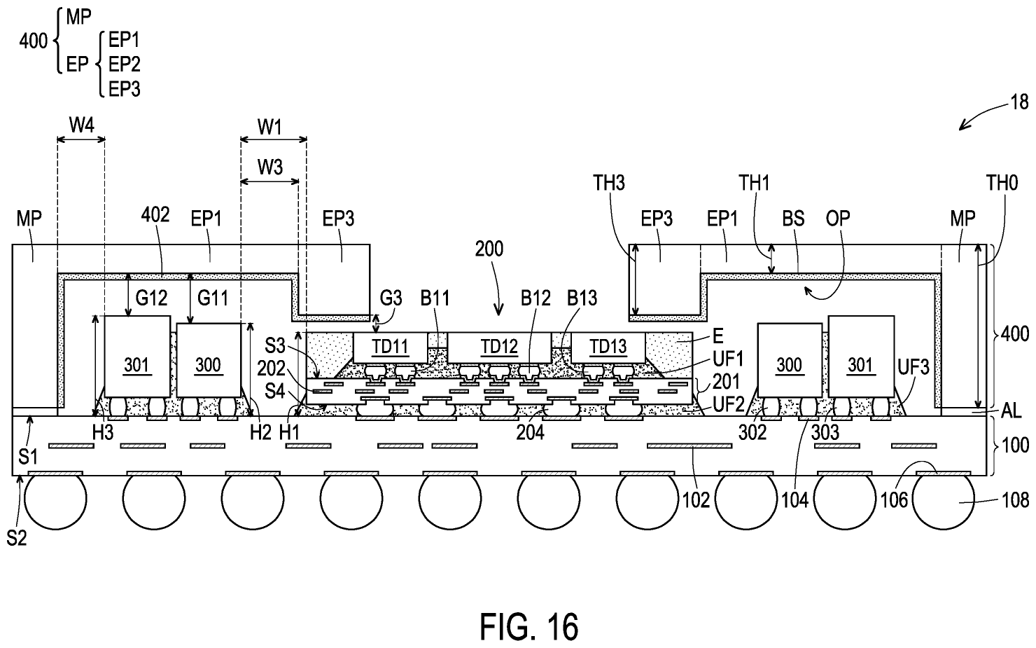

FIG. 16 is a cross-sectional view of a semiconductor structure in accordance with some embodiments. The difference between the semiconductor structure 18 and the semiconductor structure 17 lies in that, in the semiconductor structure 18, a buffer layer 402 is further attached to the ring structure 400 so as to provide more protection for the underlying semiconductor devices 300 and 301. In some embodiments, the buffer layer 402 is formed not only on the entire bottom surface BS of the extension portion EP but also on the sidewall of the main portion MP, as shown in FIG. 16.

The semiconductor structures of the disclosure are illustrated below with reference to FIG. 4 to FIG. 16.

According to some embodiments of the disclosure, a semiconductor structure 10/11/12/13/14/15/16/17/18 includes a circuit substrate 100, at least one semiconductor package 200, at least one semiconductor device 300, and a ring structure 400. The at least one semiconductor package 200 is disposed on the circuit substrate 100, and the semiconductor package 200 includes a plurality of integrated circuit structures TD11, TD12 and TD13. The integrated circuit structures TD11, TD12 and TD13 may be laterally arranged and/or vertically stacked upon the process requirements. The at least one semiconductor device 300 is disposed on the circuit substrate 100 and aside the semiconductor package 200. The ring structure 400 is disposed on the circuit board 100 and surround multiple semiconductor device 300. The ring structure 400 includes at least one opening pattern OP corresponding to the semiconductor device 300.

In some embodiments, a top surface of the semiconductor device 300 is higher than a top surface of the semiconductor package 200. In some embodiments, a width OPW of the opening pattern OP is greater than a width SDW of the semiconductor device 300.

In some embodiments, the at least one semiconductor device 15/16/17/18 includes two semiconductor devices 300 and 301, and each opening pattern OP corresponds to the two semiconductor devices 300 and 301, as show in FIG. 12 to FIG. 16.

In some embodiments, the semiconductor structure 11/12/14/16/18 further includes a buffer layer 402 disposed on a surface of the opening pattern OP. The buffer layer 402 may be attached to a portion of the bottom surface or an entire bottom surface of the extension part EP of the ring structure 400. The buffer layer 402 may further continuously extend along the sidewall of the base portion MP of the ring structure 400. In some embodiments, the buffer layer 402 is separated from the semiconductor device 300 and/or the semiconductor package 200 by a non-zero distance.

In some embodiments, from a top view or a cross-sectional view, the ring structure 400 is separated from the semiconductor package 200 by a non-zero distance, as shown in FIG. 4. FIG. 5, FIG. 6, FIG. 9, FIG. 10 and FIG. 11.

In some embodiments, from a top view or a cross-sectional view, the ring structure 400 is partially overlapped with the semiconductor package 200, as shown in FIG. 7, FIG. 8, FIG. 12, FIG. 13, FIG. 14, FIG. 15 and FIG. 16.

In some embodiments, the semiconductor package 10/11/12/13/14/15/16/17/18 further includes an interposer 201 disposed between the integrated circuit structures TD11, TD12, TD13 and the circuit substrate 100; and an encapsulation layer E disposed over the interposer 201 and encapsulating the integrated circuit structures TD11, TD12, TD13. In some embodiments, the interposer 201 is optional and may be omitted as needed.

According to some embodiments of the disclosure, a semiconductor structure 10/11/12/13/14/15/16/17/18 includes a circuit substrate 100, a plurality of integrated circuit structures TD11, TD12, TD13, an encapsulating layer E, at least one semiconductor device 300 and a ring structure 400. The integrated circuit structures TD11, TD12, TD13 are laterally disposed on and electrically connected to the circuit substrate 100. The encapsulating layer E encapsulates the integrated circuit structures TD11, TD12, TD13. The at least one semiconductor device 300 is disposed on the circuit substrate 100 and separated from the encapsulating layer E. The ring structure 400 is disposed on the circuit substrate 100. The ring structure 400 includes a base portion MP and an overhang portion EP laterally extending across the at least one semiconductor device 300 with respect to the base portion MP, wherein the overhang portion EP has at least two different thicknesses. From another point of view, the bottom surface BS (e.g., the surface facing the semiconductor device 300) of the overhang portion EP of the ring structure 400 is uneven and stepped. Such ring structure 400 is called a “stepped ring structure” in some examples.

In some embodiments, a top surface of the semiconductor device 300 is higher than a top surface of the integrated circuit structures TD11, TD12, TD13.

In some embodiments, the overhang portion EP of the ring structure 400 has a first part P1 with a first thickness and a second part P2/P3 with a second thickness, the second thickness is greater than the first thickness, and the first part P1 corresponds to the at least one semiconductor device 300.

In some embodiments, from a top view or a cross-sectional view, the second part P3 of the ring structure 400 is spaced apart from the at least one semiconductor device 300 or the integrated circuit structures TD11, TD12, TD13, as shown in FIG. 4. FIG. 5. FIG. 6, FIG. 9, FIG. 10 and FIG. 11.

In some embodiments, from a top view or a cross-sectional view, the second part P2 of the ring structure 400 is spaced apart from the at least one semiconductor device 300 but overlapped with at least one of the integrated circuit structures TD11, TD12, TD13, as shown in FIG. 7, FIG. 8, FIG. 12, FIG. 13, FIG. 14, FIG. 15 and FIG. 16. In some embodiments, the overhang portion EP of the ring structure 400 further extends over a portion of the encapsulation layer E.

In some embodiments, the overhang portion EP has a continuously varied thickness, as shown in FIG. 9 and FIG. 11.

In some embodiments, the semiconductor structure further includes a buffer layer 402 disposed on a bottom surface BS of the overhang portion EP and a sidewall of the base portion MP of the ring structure 400, as shown in FIG. 7, FIG. 11, FIG. 14 and FIG. 16.

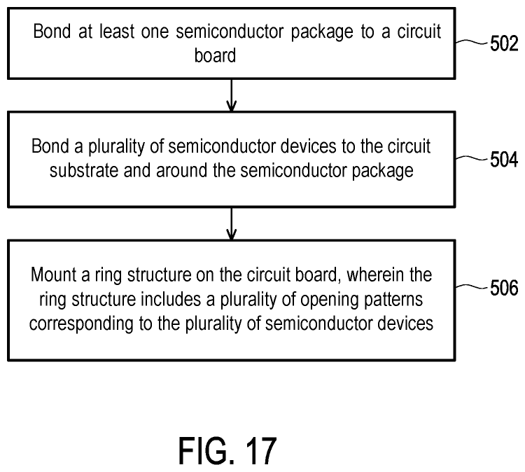

FIG. 17 illustrates a process flow of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 502, at least one semiconductor package is bonded to a circuit board. FIG. 1, FIG. 2, FIG. 4 to FIG. 16 illustrate different views corresponding to some embodiments of act 502.

At act 504, a plurality of semiconductor devices are bonded to the circuit substrate and around the semiconductor package. FIG. 3 to FIG. 16 illustrate different views corresponding to some embodiments of act 504.

At act 506, a ring structure is mounted on the circuit board, wherein the ring structure includes a plurality of opening patterns corresponding to the plurality of semiconductor devices. FIG. 4 to FIG. 16 illustrate different views corresponding to some embodiments of act 506.

In some embodiments, the method further includes, before mounting the ring structure on the circuit board, forming a buffer layer on surfaces of the opening patterns of the ring structure, as shown in FIG. 6, FIG. 7. FIG. 11, FIG. 14 and FIG. 16.

In some embodiments, from a top view or a cross-sectional view, the ring structure is separated from the semiconductor package by a non-zero distance, as shown in FIG. 4. FIG. 5, FIG. 6, FIG. 9, FIG. 10 and FIG. 11.

In some embodiments, from a top view or a cross-sectional view, the ring structure is partially overlapped with the semiconductor package, as shown in FIG. 7, FIG. 8, FIG. 12, FIG. 13, FIG. 14, FIG. 15 and FIG. 16.

In view of the above, in the disclosure, a semiconductor device includes semiconductor package(s) and semiconductor device(s) around the semiconductor package(s), which are laterally disposed and electrically connected to a circuit substrate. In some embodiments, a ring structure is disposed on the circuit substrate to encircle the semiconductor device(s). The ring structure of the disclosure has an overhang portion across the semiconductor device(s), and the overhang portion has opening pattern(s) corresponding to the underlying semiconductor device(s). In some embodiments, by including such ring structure with opening pattern(s), the warpage of the 3DIC semiconductor structure may be effectively controlled without contacting the underlying semiconductor device(s), thus enhancing yield and reliability of the semiconductor device.

According to some embodiments of the disclosure, a semiconductor structure includes a circuit substrate, at least one semiconductor package, at least one semiconductor device, and a ring structure. The at least one semiconductor package is disposed on the circuit substrate, and the semiconductor package includes a plurality of integrated circuit structures. The at least one semiconductor device, disposed on the circuit substrate and aside the semiconductor package. The ring structure is disposed on the circuit board. The ring structure includes at least one opening pattern corresponding to the semiconductor device.

According to some embodiments of the disclosure, a semiconductor structure includes a circuit substrate, a plurality of integrated circuit structures, an encapsulating layer, at least one semiconductor device and a ring structure. The integrated circuit structures are laterally disposed on the circuit substrate. The encapsulating layer encapsulates the integrated circuit structures. The at least one semiconductor device is disposed on the circuit substrate and separated from the encapsulating layer. The ring structure is disposed on the circuit substrate. The ring structure includes a base portion and an overhang portion laterally extending across the at least one semiconductor device with respect to the base portion, wherein the overhang portion has at least two different thicknesses.

According to some embodiments of the disclosure, a method of forming a semiconductor structure includes: bonding at least one semiconductor package to a circuit board; bonding a plurality of semiconductor devices to the circuit substrate and around the semiconductor package; and mounting a ring structure on the circuit board, wherein the ring structure includes a plurality of opening patterns corresponding to the plurality of semiconductor devices.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a circuit substrate;
at least one semiconductor package, disposed on the circuit substrate, wherein the semiconductor package comprises a plurality of integrated circuit structures;
at least one semiconductor device, disposed on the circuit substrate and aside the semiconductor package; and
a ring structure, disposed on the circuit board, wherein the ring structure comprises at least one opening pattern corresponding to the semiconductor device.

2. The semiconductor structure of claim 1, wherein a top surface of the semiconductor device is higher than a top surface of the semiconductor package.

3. The semiconductor structure of claim 1, wherein a width of the opening pattern is greater than a width of the semiconductor device.

4. The semiconductor structure of claim 1, wherein the at least one semiconductor device comprises two semiconductor devices, and the opening pattern corresponds to the two semiconductor devices.

5. The semiconductor structure of claim 1, further comprising a buffer layer disposed on a surface of the opening pattern.

6. The semiconductor structure of claim 1, wherein from a top view, the ring structure is separated from the semiconductor package by a non-zero distance.

7. The semiconductor structure of claim 1, wherein from a top view, the ring structure is partially overlapped with the semiconductor package.

8. The semiconductor structure of claim 1, wherein the semiconductor package further comprises:
an interposer, disposed between the integrated circuit structures and the circuit substrate; and
an encapsulation layer, disposed over the interposer and laterally encapsulating the integrated circuit structures.

9. A semiconductor structure, comprising:
a circuit substrate;
a plurality of integrated circuit structures, laterally disposed on the circuit substrate;
an encapsulating layer, laterally encapsulating the plurality of integrated circuit structures;
at least one semiconductor device, disposed on the circuit substrate and separated from the encapsulating layer; and
a ring structure, disposed on the circuit substrate, wherein the ring structure comprises a base portion and an overhang portion laterally extending across the at least one semiconductor device with respect to the base portion, wherein the overhang portion has at least two different thicknesses.

10. The semiconductor structure of claim 9, wherein a top surface of the semiconductor device is higher than a top surface of the integrated circuit structures.

11. The semiconductor structure of claim 9, wherein the overhang portion of the ring structure has a first part with a first thickness and a second part with a second thickness, the second thickness is greater than the first thickness, and the first part corresponds to the at least one semiconductor device.

12. The semiconductor structure of claim 11, wherein the second part of the ring structure is spaced apart from the at least one semiconductor device or the integrated circuit structures.

13. The semiconductor structure of claim 11, wherein the second part of the ring structure is spaced apart from the at least one semiconductor device but overlapped with at least one of the integrated circuit structures.

14. The semiconductor structure of claim 9, wherein the overhang portion has a continuously varied thickness.

15. The semiconductor structure of claim 9, further comprising a buffer layer disposed on a bottom surface of the overhang portion.

16. The semiconductor structure of claim 9, wherein the overhang portion of the ring structure further extends over a portion of the encapsulation layer.

17. A method of forming a semiconductor structure, comprising:
bonding at least one semiconductor package to a circuit board;
bonding a plurality of semiconductor devices to the circuit substrate and around the semiconductor package; and
mounting a ring structure on the circuit board, wherein the ring structure comprises a plurality of opening patterns corresponding to the plurality of semiconductor devices.

18. The method of claim 17, further comprising, before mounting the ring structure on the circuit board, forming a buffer layer on surfaces of the opening patterns of the ring structure.

19. The method of claim 17, wherein from a top view, the ring structure is separated from the semiconductor package by a non-zero distance.

20. The method of claim 17, wherein from a top view, the ring structure is partially overlapped with the semiconductor package.
